(19) United States
(12) Patent Application Publication
(10) Pub. No.: US 2026/0338848 A1
(43) Pub. Date: Oct. 29, 2026

(54) COMMUNICATION METHOD AND COMMUNICATION DEVICE FOR TRANSMITTING MESSAGES FOR AN IT POWER SUPPLY SYSTEM

(71) Applicant: Bender GmbH & Co. KG, Gruenberg (DE)

(72) Inventors: Jens Burmeister, Dresden (DE); Hendrik Wünsch, Dresden (DE)

(21) Appl. No.: 19/648,251

(22) Filed: Apr. 15, 2026

(30) Foreign Application Priority Data
Apr. 29, 2025 (DE) 10 2025 116 504.1

(51) Int. Cl. G01R 31/08

(52) U.S. Cl. CPC G01R 31/088

(57) ABSTRACT

A communication method (40) and a communication device (50) for an IT power supply system (2) for transmitting messages between a first piece of operating equipment (10) having a first current sensor (12) for registering a fault current (I_{F}, I_{Fmod}) flowing in the IT power supply system (2) and a second piece of operating equipment (20) having a second current sensor (22) for registering the fault current (I_{F}, I_{Fmod}), the first piece of operating equipment (10) being connected between an active conductor of the IT power supply system (2) and ground potential (PE) and the message is transmitted by modulating the fault current (I_{F}, I_{Fmod}). This allows communication between two pieces in an IT network without these pieces of operating equipment necessarily having explicit wired or wireless communication interfaces via their connection for measuring purposes. Communication takes place exclusively via the interfaces which register the fault current and are already available for recording measured values.

This application claims the benefit of German Patent Application No. 10 2025 116 504.1 filed on Apr. 29, 2025, the disclosure of which is incorporated herein by reference.

### TECHNICAL FIELD

The invention relates to a communication method and to a communication device for transmitting messages for an IT power supply system, the communication device having a first piece of operating equipment having a first current sensor for registering a fault current flowing in the IT power supply system and a second piece of operating equipment having a second current sensor for registering the fault current, the first piece of operating equipment being connected between an active conductor of the IT power supply system and ground potential.

### BACKGROUND

When there are increased requirements for the operational, fire, and touch safety of electrical systems, an ungrounded power supply system is used, which is also referred to as an isolated network (French: “Isolé Terre”—IT) or an IT power supply system. In this type of power supply system, the active parts (active conductors of the IT system) are isolated from the ground potential—to ground. The exposed conductive parts of the connected electrical consumers are applied to the ground potential individually or collectively via a protective conductor. The advantage of these networks is that, in the event of an insulation fault, the operability of the connected electrical consumers is not impaired, as no closed circuit can form due to the ideally infinitely large insulation resistance value between an active conductor of the IT network and ground. Operation of the IT network can therefore continue despite a first insulation fault.

In the IT network, operating equipment (measuring devices) can or, in the case of an insulation monitoring device in conjunction with an insulation fault location system, must be temporarily or permanently installed. In order for these measuring devices to be able to communicate with each other, a suitable communication method for exchanging messages is required. The transmission of a message presumes suitable communication interfaces in the operating equipment.

The technological prerequisites for a wired or wireless communication interface in the corresponding pieces of operating equipment which communicate with each other, however, are often not available. While stationary insulation monitoring devices, which are prescribed by standards, typically comprise an external communication channel (e.g., the Modbus protocol) in order to be able to communicate with the outside world (intranet/internet), there are often limitations regarding communication within the operating equipment connected to the IT network for cost reasons and security aspects. In particular in mobile operating equipment, such as portable insulation fault location devices, wired couplings in the IT network via, for example, Modbus, UART or CAN busses, are problematic, since these devices typically do not have direct communication interfaces.

In certain operating environments, requirements to the device casing regarding impermeability and electrical safety are higher. An additional conductor-bound interface always means an additional casing opening, which should be avoided, as, for example, cleaning or sanitizing agents could enter the casing. Another difficulty which arises from these requirements is that devices shut by single-use screws cannot be readily opened for connecting an application programming interface or a diagnostic connector, for example.

As a rule, the electric circuit in a (portable) device is also not galvanically separated from the power supply system, as an additional wired communication interface having galvanic separation would make the device's design more intricate and the device thus more expensive.

Aside from the aspect of cost, wireless interfaces for transmitting messages, e.g., by means of WLAN, Bluetooth or Zigbee, also have disadvantageous technical effects, as they can disturb the functionality of electrical medical devices due to their possible electromagnetic mutual impedance in secured operating environments, such as in certain hospital areas.

### SUMMARY

The object of the invention at hand is therefore to design a method and a device which implements this method, both the method and the device enabling a technologically reliable and cost-efficient transmission of messages between any two pieces of operating equipment connected in an IT power supply system.

In conjunction with the features of the subject matter in claim 1, this object is attained in that messages are transmitted by modulating the fault current.

The base for observations is the first piece of operating equipment via whose first current sensor at least one electrically conductive connection is established between one of the active conductors of the IT power supply system and the ground potential. The first piece of operating equipment can be a permanently installed insulation monitoring device, for example, which is prescribed by standards.

The fundamental idea of the invention is based on using a forced fault current flowing in one of the active conductors of the IT network in order to transmit messages. The messages are then transmitted between the first piece of operating equipment which has the first current sensor for registering the fault current flowing in the IT power supply system and the second piece of operating equipment connected in the IT network and having the second current sensor.

The active conductors of the IT network, to which the first and second piece of operating equipment are connected for measuring purposes, for example in the form of a combination of measuring devices, such as an insulation monitoring device and an insulation fault location device, thus provide the physical (structural) message transmission channel, meaning explicit communication interfaces for a wired or wireless message transmission between the operating equipment are not required. A fault current modulated according to the message to be transmitted thus represents the information-containing signal as a physical variable.

The invention enables communication between two pieces of operating equipment in an IT network, without these pieces of operating equipment having to include explicit wired or wireless communication interfaces beyond their connections for measuring purposes. The communication takes place exclusively via the interfaces which register the fault current and are already available for recording measured values.

In the further embodiment, the communication method comprises the following steps: establishing a temporary ground coupling between one of the active conductors of the IT power supply system and the ground potential by means of a ground-coupling switching device in the second piece of operating equipment to force the fault current; registering the fault current in the first piece of operating equipment by means of the first current sensor; modulating the fault current via the first piece of operating equipment for transmitting a message to the second piece of operating equipment; registering the modulated fault current in the second piece of operating equipment by means of the second current sensor; demodulating the modulated fault current in the second piece of operating equipment; disconnecting the temporary ground coupling by means of the ground-coupling switching device; and evaluating the message in the second piece of operating equipment.

First, a ground-coupling switching device establishes a temporary ground coupling between one of the active conductors of the IT power supply system and the ground potential in the second piece of operating equipment for the duration of the message transmission. This coupling of the ground to the ground potential does not necessarily have to be a saturated ground fault with the protective conductor, but can also be implemented as an ohmic coupling in the form of a current-limiting high-impedance coupling or as a capacitive coupling in alternative voltage networks.

As a result of the ground coupling, an unmodulated fault current is initially forced. This fault current flows back to the first piece of operating equipment via the coupled active conductor, via the ground-coupling switching device acting as the provoked insulation fault (ground coupling) and via the protective conductor (ground). In the first piece of operating equipment, the unmodulated fault current is registered by the first current sensor, which closes the fault-current circuit.

The still unmodulated fault current provoked by the second piece of operating equipment is modulated in the first piece of operating equipment according to the message to be transmitted and thus becomes a modulated fault current. Within the IT network, the first piece of operating equipment can thus be viewed as a message source for transmitting the message introduced externally via the external connection of the first piece of operating equipment to the second piece of operating equipment.

The second piece of operating equipment acts as a sink and registers the modulated fault current by means of the second current sensor. For information retrieval, the modulated fault current is demodulated, the message is evaluated and lastly, the temporary ground coupling is disconnected by means of the ground-coupling switching device.

Advantageously, the message is transmitted between an insulation monitoring device designed as a first piece of operating equipment and an insulation fault location device designed as a second piece of operating equipment.

Since IT power supply systems have to be equipped with standardized insulation monitoring devices, it is of particular advantage if an insulation monitoring device of this kind is used as the first piece of operating equipment and a (portable) insulation fault location device for locating an insulation fault is used as the second piece of operating equipment. This combination of measuring devices thus allows transmitting configuration data, for example, to the insulation fault location device from the insulation monitoring device connected to the outside world without further internal communication interfaces.

Furthermore, the fault current is registered in the insulation monitoring device using a series resistance as a first current sensor and in the insulation fault location device using a measuring current transformer as a second current sensor.

When using an insulation monitoring device as the first piece of operating equipment and an insulation fault location device as the second piece of operating equipment, the first current sensor is designed as a current-limiting series resistor in which a voltage drop caused by the fault current and thus the fault current itself is identified. The second current sensor in the second piece of operating equipment is preferably designed as a measuring current transformer for registering the modulated fault current.

Preferably, the fault current is modulated by means of amplitude modulation.

The information to be transmitted is contained in the amplitude curve of the fault current in this modulation type, the modulation taking place value-and time-discreetly in digital form with preferably rectangular pulses (binary or multi-level amplitude shift keying).

Furthermore, a channel encoding of the message takes place.

As protection from transmission errors in the fault-current circuit, additional information in the form of an error-correcting or error-identifying coding can be included in the message.

The functional units, such as the current sensors, the ground-coupling switching device, the modulator/demodulator and the evaluation unit, claimed as structural features in the communication device according to the invention implement the corresponding method steps of the method according to the invention. Consequently, technical effects attained using the method and the advantages resulting therefrom pertain equally to the communication device.

### BRIEF DESCRIPTION OF THE DRAWINGS

Further advantageous embodiment features are derived from the following description and the drawings, which describe a preferred embodiment of the invention using examples.

FIG. 1 shows an overview block diagram of the communication device according to the invention for an IT power supply system.

FIG. 2 shows a functional block diagram of the first and second piece of operating equipment in the IT power supply system.

FIG. 3 shows a flow diagram of the communication method according to the invention.

### DETAILED DESCRIPTION

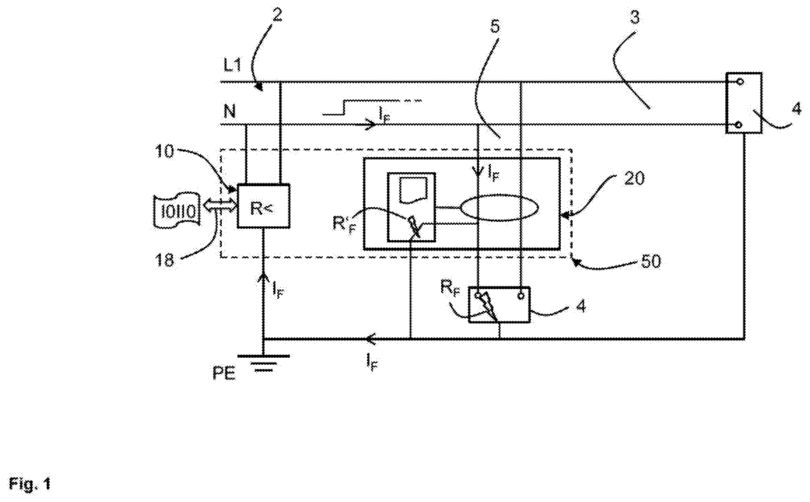

FIG. 1 shows an overview block diagram of the communication device 50 according to the invention for an IT power supply system 2.

Communication device 50 according to the invention consists of a first piece of operating equipment 10 and a second piece of operating equipment 20, which can each be connected to at least one of active conductors L1, N of IT power supply system 2 and protective conductor PE (ground potential).

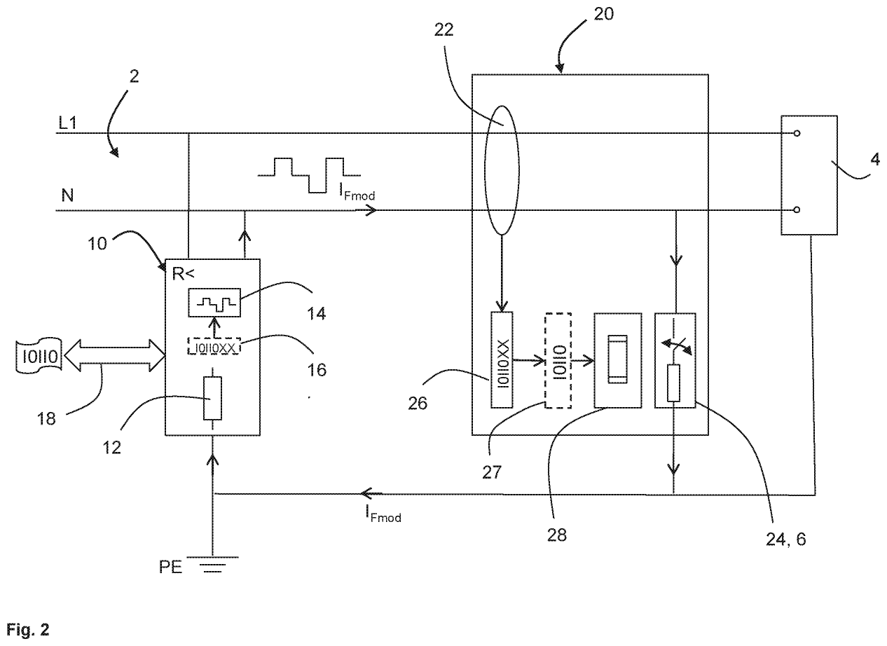

A load 4 grounded via protective conductor PE is connected to IT power supply system 2 in both main system 3 and subsystem 5. To demonstrate a fault-current circuit, an actual insulation fault R_{F} is presumed on load 4 of subsystem 5 between active conductor N (in this case the neutral conductor) and protective conductor PE. Insulation fault R_{F} causes fault current I_{F}, which is identified by first current sensor 12 (FIG. 2) in first piece of operating equipment 10 as well as by second current sensor 22 (FIG. 2) in second piece of operating equipment 20.

To implement communication method 40 according to the invention, a provoked insulation fault R′_{F} in the form of temporary ground coupling 6 (FIG. 2) is triggered in second piece of operating equipment 20.

First piece of operating equipment 10 has a communication channel 18 to an external area, such as a superordinate control, via which configuration parameters or control information can be transmitted to operating equipment 10, 20 connected in IT power supply system 2.

In an example, first piece of operating equipment 10 is designed as an insulation monitoring device. Generally, however, first piece of operating equipment 10 can be designed in any manner as long as it fulfills the requirement of having a first current sensor 12, via which first piece of operating equipment 10 is connected to ground potential PE in order to close the fault-current circuit in the event of a (insulation) fault and to identify fault current I_{F} flowing therein.

FIG. 2 shows a functional block diagram of first and second pieces of operating equipment connected in IT power supply system 2. The illustration shows the communication in the state in which shown modulated fault current I_{Fmod} is generated as the message-carrying signal after forced fault current I_{F} has been generated and registered.

First piece of operating equipment 10 (insulation monitoring device) comprises first current sensor 12 for registering fault current I_{F} forced by ground-coupling switching device 24 of second piece of operating equipment 20 (insulation fault location device), and a modulator 14, which preferably is designed as an amplitude modulator. Modulator 14 forms modulated fault current I_{Fmod} from forced fault current I_{F}. In addition, first piece of operating equipment 10 can optionally have a channel encoder 16 in order to identify and correct transmission errors.

A demodulator 26 in second piece of operating equipment 20 demodulates modulated fault current I_{Fmod} and forwards the demodulated message to an evaluation unit 28 after a channel decoding 27, if required.

In an example, second piece of operating equipment 20 is designed as an insulation fault location device, which is installed for locating an actual insulation fault R_{F} (FIG. 1) in the IT power supply system for locating an actual insulation fault R_{f} previously identified by the insulation monitoring device. Second piece of operating equipment 20 can also be designed as any (measuring) device, provided it fulfills the requirement of having a second current sensor 22 for identifying fault currents I_{F}, I_{Fmod}.

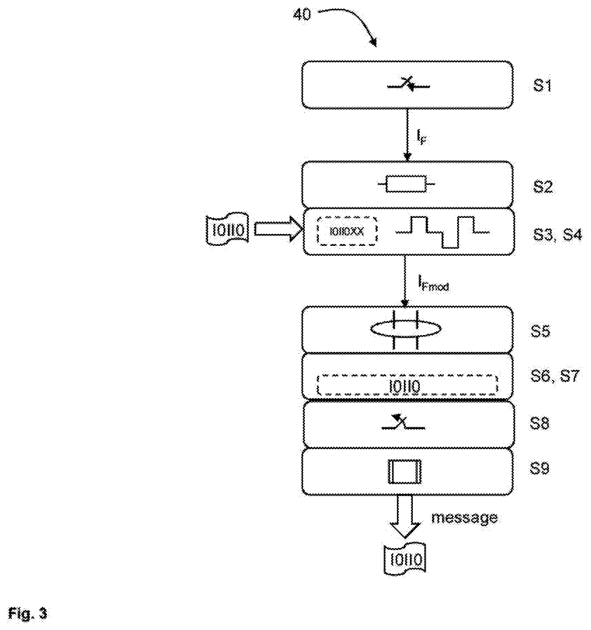

FIG. 3 shows a flow diagram of the communication method 40 according to the invention.

Assuming that first piece of operating equipment 10 has established a connection between one of the active conductors L1, N via first current sensor 12, a temporary connection (temporary ground coupling 6) to protective conductor PE which exists for the duration of the message transmission is established by means of ground-coupling switching device 24 in second piece of operating equipment 20 in step S1 so that a current circuit is created in which fault current I_{F} can flow.

Fault current I_{F} should have a sufficiently high amplitude in order to be able to differentiate it from simultaneously occurring actual fault currents. An amplitude of several mA, for example 3 mA, seems suitable. More progressive modulation methods going beyond binary transmission can allow lower fault-current amplitudes in the range of under 1 mA in conjunction with a channel encoding.

Fault current I_{F} is registered by first current sensor 12 of first piece of operating equipment 10 in step S2 and modulated in step S4 according to the message to be transmitted, which results in modulated fault current I_{Fmod}. Optionally, a channel encoding S3 is switched upstream of modulation S4 for interference-resistant message transmission.

Modulated fault current I_{Fmod} is registered in second piece of operating equipment 20 by second current sensor 22 in step S5, demodulated in step S6 and, if required, channel-decoded in step S7. Subsequently, temporary ground coupling 6 can be disconnected by means of ground-coupling switching device 24 in step S8, and the message can be evaluated in step S9 by, for example, configuration parameters being automatically set in second piece of operating equipment 20.

1. A communication method (40) for an IT power supply system (2) for transmitting a message between a first piece of operating equipment (10) having a first current sensor (12) for registering a fault current (I_{F}, I_{Fmod}) flowing in the IT power supply system (2) and a second piece of operating equipment (20) having a second current sensor (22) for registering the fault current (I_{F}, I_{Fmod}), the first piece of operating equipment (10) being connected between an active conductor of the IT power supply system (2) and ground potential (PE), comprising the step of transmitting the message by modulating the fault current (I_{F}, I_{Fmod}).

2. The communication method (40) according to claim 1,
further including the steps of:
establishing (S1) a temporary ground coupling (6) between one of the active conductors of the IT power supply system (2) and the ground potential (PE) by means of a ground-coupling switching device (24) in the second piece of operating equipment (20) to force the fault current (I_{F}), registering (S2) the fault current (I_{F}) in the first piece of operating equipment (10) by means of the first current sensor (12),
modulating (S4) the fault current (I_{F}) via the first piece of operating equipment (10) for transmitting the message to the second piece of operating equipment (20),
registering (S5) the modulated fault current (I_{Fmod}) in the second piece of operating equipment (20) by means of the second current sensor (22),
demodulating (S6) the modulated fault current (I_{Fmod}) in the second piece of operating equipment (20),
disconnecting (S8) the temporary ground coupling (6) by means of the ground-coupling switching device (24), and
evaluating (S9) the message in the second piece of operating equipment (20).

3. The communication method (40) according to claim 1,
wherein
the message is transmitted between an insulation monitoring device designed as a first piece of operating equipment (10) and an insulation fault location device designed as a second piece of operating equipment (20).

4. The communication method (40) according to claim 3,
wherein
the fault current (I_{F}) is registered (S2) in the insulation monitoring device using a series resistance as a first current sensor (12) and in the insulation fault location device using a measuring current transformer as a second current sensor (22).

5. The communication method (40) according to claim 2,
wherein
the fault current (I_{F}) is modulated (S4) by means of amplitude modulation.

6. The communication method (40) according to claim 2,
wherein
a channel encoding (S3) of the message takes place.

7. A communication device (50) for transmitting messages for an IT power supply system (2), the communication device (50) having a first piece of operating equipment (10) having a first current sensor (12) for registering a fault current (I_{F}, I_{Fmod}) flowing in the IT power supply system (2) and having a second piece of operating equipment (20) having a second current sensor (22) for registering the fault current (I_{F}, I_{Fmod}), the first piece of operating equipment (10) being connected between an active conductor of the IT power supply system (2) and ground potential (PE),
wherein
the fault current (I_{F}, I_{Fmod}) is modulated for message transmission.

8. The communication device (50) according to claim 7,
wherein
the second piece of operating equipment (20) has a ground-coupling switching device (24) for establishing a temporary ground coupling (6) between one of the active conductors of the IT power supply system (2) and the ground potential (PE) in order to force the fault current (I_{F}),
the first piece of operating equipment (10) has a modulator (14) for modulating the fault current (I_{F}) in order to transmit a message to the second piece of operating equipment (20),
the second piece of operating equipment has a demodulator (26) for demodulating the modulated fault current (I_{Fmod}), and
the second piece of operating equipment (20) has an evaluation unit (28) for evaluating the message.

9. The communication device (50) according to claim 7,
wherein
the first piece of operating equipment (10) is an insulation monitoring device and the second piece of operating equipment (20) is an insulation fault location device.

10. The communication device (50) according to claim 9,
wherein
the first current sensor (12) is designed as a series resistor and the second current sensor (22) is designed as a measuring current transformer.

11. The communication device (50) according to claim 8,
wherein
the modulator (14) is designed as an amplitude modulator and the demodulator (26) is designed as an amplitude demodulator.

12. The communication device (50) according to claim 8,
wherein
the first piece of operating equipment (10) has a channel encoder (16) and the second piece of operating equipment (20) has a channel decoder (27).
